(19) United States
(12) Patent Application Publication
(10) Pub. No.: US 2011/0011828 A1
(43) Pub. Date: Jan. 20, 2011

(54) ORGANICALLY MODIFIED ETCH CHEMISTRY FOR ZNO TCO TEXTURING

(75) Inventors: Roman Gouk, San Jose, CA (US); Steven Verhaverbeke, San Francisco, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/505,901

(22) Filed: Jul. 20, 2009

(51) Int. Cl. C23F 1/02; C23C 14/34

(52) U.S. Cl. 216/13

(57) ABSTRACT

Embodiments disclosed herein generally relate to a process of texturing a transparent conductive oxide layer deposited over a substrate. The transparent oxide layer is sometimes deposited onto a substrate for later use in a solar cell device. After the transparent conductive oxide layer is deposited, the layer is textured to increase the haze of the layer. An increase in haze permits the layer to increase light trapping and thus improve the efficiency of a solar cell. A wet etch chemistry that utilizes a component that is less polar than water permits the acidic component, such as nitric acid, to dissociate less and thus etch the transparent conductive oxide to the desired texture. A suitable component is an organic component such as acetic acid which has a dielectric constant substantially below the dielectric constant of water.

### BACKGROUND OF THE INVENTION

1. Field of the Invention

Embodiments disclosed herein generally relate to a process of texturing a transparent conductive oxide layer formed over a substrate.

2. Description of the Related Art

Photovoltaic (PV) devices or solar cells are devices which convert sunlight into direct current (DC) electrical power. PV or solar cells typically have one or more p-n junctions. Each junction comprises two different regions within a semiconductor material where one side is denoted as the p-type region and the other as the n-type region. When the p-n junction of the PV cell is exposed to sunlight (consisting of energy from photons), the sunlight is directly converted to electricity through the PV effect. PV solar cells generate a specific amount of electric power and cells are tiled into modules sized to deliver the desired amount of system power. PV modules are created by connecting a number of PV solar cells and are then joined into panels with frames and connectors.

Several types of silicon films, including microcrystalline silicon film (μc-Si), amorphous silicon film (a-Si), polycrystalline silicon film (poly-Si) and the like, may be utilized to form PV devices. A transparent conductive film, sometimes referred to as a transparent conductive oxide (TCO) may be used as a top surface electrode disposed on the top of the PV solar cells. Furthermore, the TCO layer may be disposed between a substrate and a photoelectric conversion unit as a contact layer. The TCO should have high optical transmittance in the visible or higher wavelength region to facilitate transmitting sunlight into the solar cells without adversely absorbing or reflecting light energy. Additionally, low contact resistance and high electrical conductivity of the TCO are desired to provide high photoelectric conversion efficiency and electricity collection. A certain degree of texture or surface roughness of the TCO is also desired to assist sunlight trapping in the films by promoting light scattering. Overly high impurities or contaminant of the TCO often result in high contact resistance at the interface of the TCO and adjacent films, thereby reducing carrier mobility within the PV cells. Furthermore, insufficient transparency of the TCO may adversely reflect light back to the environment, resulting in a diminished amount of sunlight entering the PV cells and a reduction in the photoelectric conversion efficiency.

Therefore, there is a need for an improved method for fabricating a TCO.

### SUMMARY OF THE INVENTION

Embodiments disclosed herein generally relate to a process of texturing a transparent conductive oxide layer deposited over a substrate. The transparent oxide layer is sometimes deposited onto a substrate for later use in a solar cell device. After the transparent conductive oxide layer is deposited, the layer is textured to increase the haze of the layer. An increase in haze permits the layer to increase light trapping and thus improve the efficiency of a solar cell. A wet etch chemistry that utilizes a component that is less polar than water permits the acidic component, such as nitric acid, to dissociate less and thus etch the transparent conductive oxide to the desired texture. A suitable component is an organic component such as acetic acid which has a dielectric constant substantially below the dielectric constant of water.

In one embodiment, a method of forming a transparent conductive oxide layer over a substrate is disclosed. The method includes sputter depositing a zinc oxide layer over a substrate and etching the zinc oxide layer with a solution having a pH of less than about 2 and at least one component having a dielectric constant of less than about 20.

In another embodiment, a method of forming a transparent conductive oxide layer over a substrate is disclosed. The method includes sputter depositing a zinc oxide layer over a substrate and etching the zinc oxide layer with a solution comprising a first component having a dielectric constant of less than about 20.

In another embodiment, a method of forming a transparent conductive oxide layer over a substrate is disclosed. The method includes sputter depositing a zinc oxide layer over a substrate and etching the zinc oxide layer with a solution comprising a first component having a surface tension of less than about 30 dyne/cm².

In another embodiment, a method of forming a transparent conductive oxide layer over a substrate is disclosed. The method includes sputter depositing a zinc oxide layer over a substrate and annealing the sputter deposited zinc oxide layer. The method also includes etching the annealed zinc oxide layer to form a roughened surface on the zinc oxide layer. The etching comprises exposing the zinc oxide layer to a wet etchant comprising nitric acid and acetic acid.

In another embodiment, a method of forming a transparent conductive oxide layer over a substrate is disclosed. The method includes sputter depositing a zinc oxide layer over a substrate, etching the sputter deposited zinc oxide layer to form a roughened surface on the zinc oxide layer and annealing the etched zinc oxide layer. The etching comprises exposing the zinc oxide layer to a wet etchant comprising nitric acid and acetic acid.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic cross-sectional view of one embodiment of a process chamber in accordance with the invention.

FIG. 2 depicts a schematic cross-sectional view of another embodiment of a process chamber in accordance with the invention.

FIG. 3 depicts an exemplary cross sectional view of a crystalline silicon-based thin film PV solar cell in accordance with one embodiment of the present invention.

FIG. 4 depicts an exemplary cross sectional view of a tandem type PV solar cell in accordance with one embodiment of the present invention.

FIG. 5A shows a TCO surface after etching with a solution of 0.4 volume percent HCl for 30 seconds.

FIG. 5B shows a TCO surface after etching with a solution of acetic acid and nitric acid.

FIG. 6 is a graph showing the relationship between haze and etching for various etching chemistries.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments disclosed herein generally relate to a process of texturing a transparent conductive oxide layer deposited over a substrate. The transparent oxide layer is sometimes deposited onto a substrate for later use in a solar cell device. After the transparent conductive oxide layer is deposited, the layer is textured to increase the haze of the layer. An increase in haze permits the layer to increase light trapping and thus improve the efficiency of a solar cell. A wet etch chemistry that utilizes a component that is less polar than water permits the acidic component, such as nitric acid, to dissociate less and thus etch the transparent conductive oxide to the desired texture. A suitable component is an organic component such as acetic acid which has a dielectric constant substantially below the dielectric constant of water.

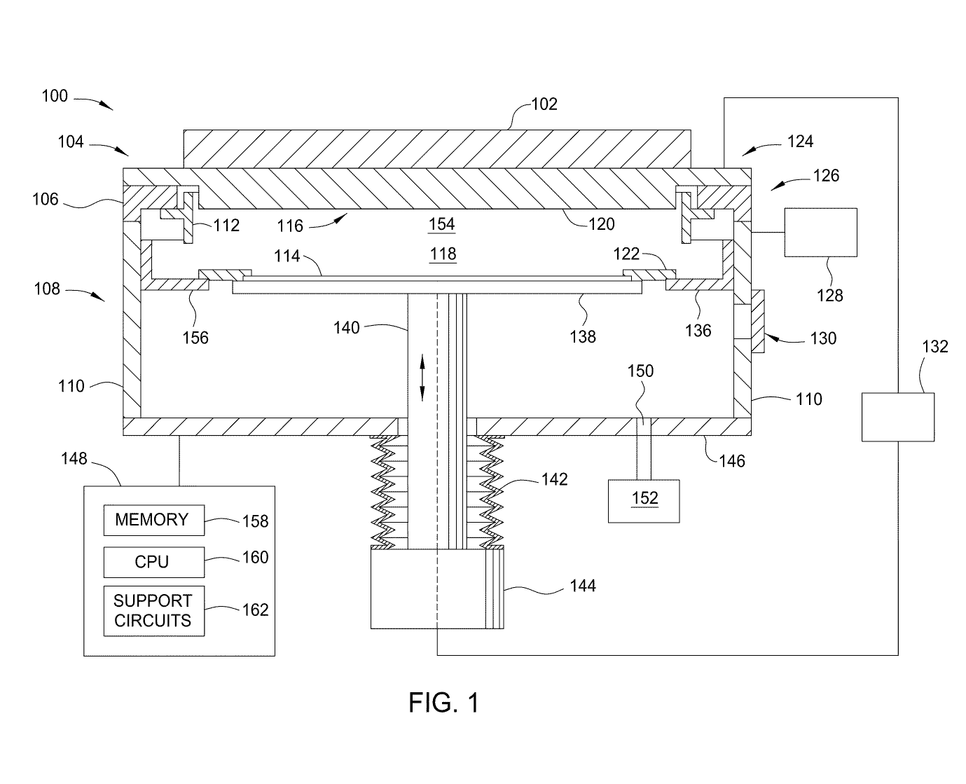

FIG. 1 illustrates an exemplary reactive sputter process chamber 100 suitable for sputter depositing materials according to one embodiment of the invention. One example of the process chamber that may be adapted to benefit from the invention is a PVD process chamber, available from Applied Materials, Inc., located in Santa Clara, Calif. It is contemplated that other sputter process chambers, including those from other manufactures, may be adapted to practice the present invention.

The process chamber 100 includes a chamber body 108 having a processing volume 118 defined therein. The chamber body 108 has sidewalls 110 and a bottom 146. The dimensions of the chamber body 108 and related components of the process chamber 100 are not limited and generally are proportionally larger than the size of the substrate 114 to be processed. Any substrate size may be processed in a suitably configured chamber. Examples of suitable substrate sizes include substrate having a surface area of about 2,000 centimeter square or more, such as about 4,000 centimeter square or more, for example about 10,000 centimeter square or more. In one embodiment, a substrate having a surface area of about 50,000 centimeter square or more or more may be processed.

A chamber lid assembly 104 is mounted on the top of the chamber body 108. The chamber body 108 may be fabricated from aluminum or other suitable materials. A substrate access port 130 is formed through the sidewall 110 of the chamber body 108, facilitating the transfer of a substrate 114 (i.e., a solar panel, a flat panel display substrate, a semiconductor wafer, or other workpiece) into and out of the process chamber 100. The access port 130 may be coupled to a transfer chamber and/or other chambers of a substrate processing system.

A gas source 128 is coupled to the chamber body 108 to supply process gases into the processing volume 118. In one embodiment, process gases may include inert gases, non-reactive gases, and reactive gases. Examples of process gases that may be provided by the gas source 128 include, but not limited to, argon gas (Ar), helium (He), nitrogen gas (N₂), oxygen gas (O₂), H₂, NO₂, N₂O and H₂O among others.

A pumping port 150 is formed through the bottom 146 of the chamber body 108. A pumping device 152 is coupled to the process volume 118 to evacuate and control the pressure therein. In one embodiment, the pressure level of the process chamber 100 may be maintained at about 1 Torr or less. In another embodiment, the pressure level of the process chamber 100 may be maintained at about 10⁻³ Torr or less. In yet another embodiment, the pressure level of the process chamber 100 may be maintained at about 10⁻⁵ Torr to about 10⁻⁷ Torr. In another embodiment, the pressure level of the process chamber 100 may be maintained at about 10⁻⁷ Torr or less.

The lid assembly 104 generally includes a target 120 and a ground shield assembly 126 coupled thereto. The target 120 provides a material source that can be sputtered and deposited onto the surface of the substrate 114 during a PVD process. The target 120 or target plate may be fabricated from a material utilized for deposition species. A high voltage power supply, such as a power source 132, is connected to the target 120 to facilitate sputtering materials from the target 120. In one embodiment, the target 120 may be fabricated from a material containing zinc (Zn) metal. In another embodiment, the target 120 may be fabricated from materials including metallic zinc (Zn) containing target, zinc alloy, zinc and aluminum alloy and the like. In yet another embodiment, the target 120 may be fabricated from materials including a zinc containing material and an aluminum containing material. In one embodiment, the target may be fabricated from a zinc oxide and aluminum oxide material.

In one embodiment, the target 120 is fabricated from a zinc and aluminum alloy having a desired ratio of zinc element to aluminum element fabricated in the target 120. The aluminum elements formed in the target 120 assists in maintaining the target conductivity at a certain range so as to efficiently enable a uniform sputter process across the target surface. The aluminum elements in the target 120 are also believed to increase film transmittance when sputtered off and deposited onto the substrate. In one embodiment, the concentration of the aluminum element formed in the zinc target 120 is controlled at less than about 5 percent by weight. In the embodiment wherein the target 120 is fabricated from ZnO and Al₂O₃ alloy, the Al₂O₃ dopant concentration in the ZnO target is controlled at less than about 3 percent by weight, for example about less than 2 percent by weight, such as about less than 0.5 percent by weight, for example, about 0.25 percent by weight.

The target 120 generally includes a peripheral portion 124 and a central portion 116. The peripheral portion 124 is disposed over the sidewalls 110 of the chamber 100. The central portion 116 of the target 120 may have a curvature surface slightly extending towards the surface of the substrate 114 disposed on a substrate support 138. The spacing between the target 120 and the substrate support 138 is maintained between about 50 mm and about 150 mm during processing. It is noted that the dimension, shape, materials, configuration and diameter of the target 120 may be varied for specific process or substrate requirements. In one embodiment, the target 120 may further include a backing plate having a central portion bonded and/or fabricated from a material desired to be sputtered onto the substrate surface. The target 120 may also include adjacent tiles or material segments that together form the target.

Optionally, the lid assembly 104 may further comprise a magnetron assembly 102 mounted above the target 120 which enhances efficient sputtering materials from the target 120 during processing. Examples of the magnetron assembly 102 include a linear magnetron, a serpentine magnetron, a spiral magnetron, a double-digitated magnetron, a rectangularized spiral magnetron, among others. Additionally, the target 120 may be a cylindrical, rotatable sputtering target assembly in which the magnet assembly is within the inner core of the target assembly.

The ground shield assembly 126 of the lid assembly 104 includes a ground frame 106 and a ground shield 112. The ground shield assembly 126 may also include other chamber shield member, target shield member, dark space shield, dark space shield frame. The ground shield 112 is coupled to the peripheral portion 124 by the ground frame 106 defining an upper processing region 154 below the central portion of the target 120 in the process volume 118. The ground frame 106 electrically insulates the ground shield 112 from the target 120 while providing a ground path to the chamber body 108 of the process chamber 100 through the sidewalls 110. The ground shield 112 constrains plasma generated during processing within the upper processing region 154 and dislodges target source material from the confined central portion 116 of the target 120, thereby allowing the dislodged target source to be mainly deposited on the substrate surface rather than chamber sidewalls 110. In one embodiment, the ground shield 112 may be formed by one or more work-piece fragments and/or a number of these pieces bonding by a substrate process, such as welding, gluing, high pressure compression, etc.

A shaft 140 extending through the bottom 146 of the chamber body 108 couples to a lift mechanism 144. The lift mechanism 144 is configured to move the substrate support 138 between a lower transfer position and an upper processing position. A bellows 142 circumscribes the shaft 140 and couples to the substrate support 138 to provide a flexible seal therebetween, thereby maintaining vacuum integrity of the chamber processing volume 118.

A shadow frame 122 is disposed on the periphery region of the substrate support 138 and is configured to confine deposition of source material sputtered from the target 120 to a desired portion of the substrate surface. A chamber shield 136 may be disposed on the inner wall of the chamber body 108 and have a lip 156 extending inward to the processing volume 118 configured to support the shadow frame 122 disposed around the substrate support 138. As the substrate support 138 is raised to the upper position for processing, an outer edge of the substrate 114 disposed on the substrate support 138 is engaged by the shadow frame 122 and the shadow frame 122 is lifted up and spaced away from the chamber shield 136. When the substrate support 138 is lowered to the transfer position adjacent to the substrate transfer port 130, the shadow frame 122 is set back on the chamber shield 136. Lift pins (not shown) are selectively moved through the substrate support 138 to list the substrate 114 above the substrate support 138 to facilitate access to the substrate 114 by a transfer robot or other suitable transfer mechanism.

A controller 148 is coupled to the process chamber 100. The controller 148 includes a central processing unit (CPU) 160, a memory 158, and support circuits 162. The controller 148 is utilized to control the process sequence, regulating the gas flows from the gas source 128 into the chamber 100 and controlling ion bombardment of the target 120. The CPU 160 may be of any form of a general purpose computer processor that can be used in an industrial setting. The software routines can be stored in the memory 158, such as random access memory, read only memory, floppy or hard disk drive, or other form of digital storage. The support circuits 162 are conventionally coupled to the CPU 160 and may comprise cache, clock circuits, input/output subsystems, power supplies, and the like. The software routines, when executed by the CPU 160, transform the CPU into a specific purpose computer (controller) 148 that controls the process chamber 100 such that the processes are performed in accordance with the present invention. The software routines may also be stored and/or executed by a second controller (not shown) that is located remotely from the chamber 100.

During processing, the material is sputtered from the target 120 and deposited on the surface of the substrate 114. The target 120 and the substrate support 138 are biased relative to each other by the power source 132 to maintain a plasma formed from the process gases supplied by the gas source 128. The ions from the plasma are accelerated toward and strike the target 120, causing target material to be dislodged from the target 120. The dislodged target material and process gases forms a layer on the substrate 114 with desired compositions. In some in-line embodiments, the sputtering target 120 may be biased relative to a floating anode such as the substrate 114, the chamber wall, another target or even another electrode.

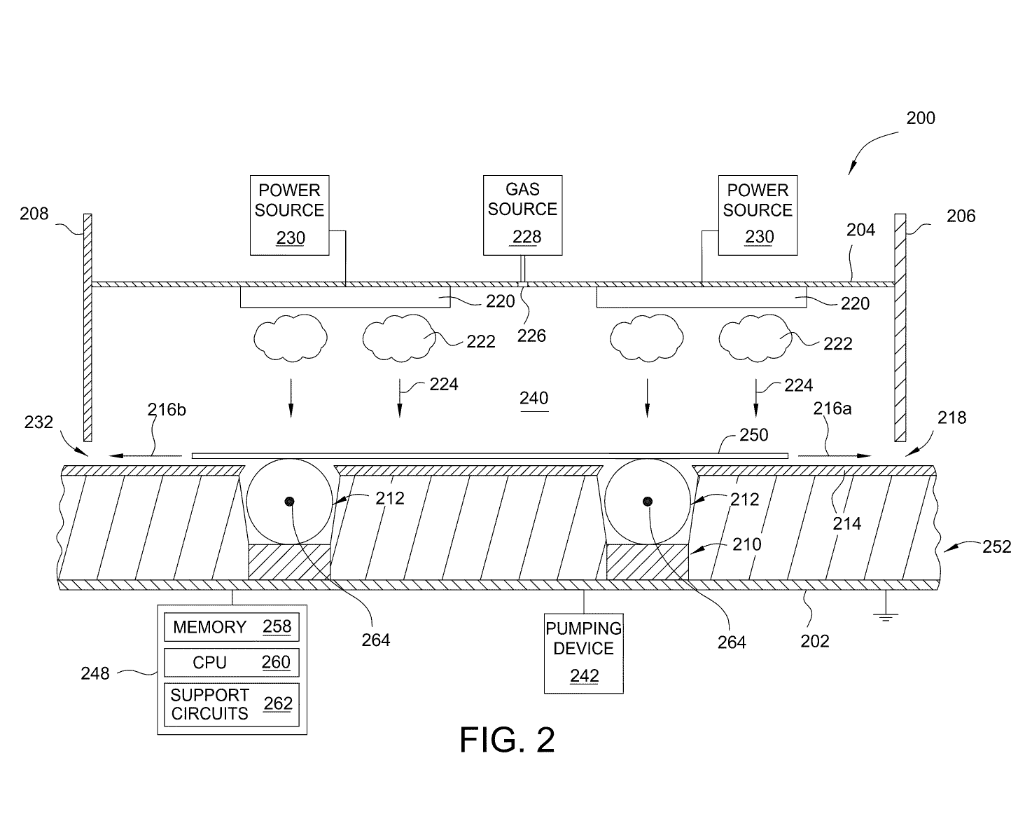

FIG. 2 illustrates another exemplary reactive sputter process chamber 200 suitable for sputter depositing materials according to one embodiment of the invention. One example of the process chamber that may be adapted to benefit from the invention is a PVD process chamber, available from Applied Materials, Inc., located in Santa Clara, Calif. It is contemplated that other sputter process chambers, including those from other manufactures, may be adapted to practice the present invention.

The processing chamber 200 includes a top wall 204, a bottom wall 202, a front wall 206 and a back wall 208, enclosing an interior processing region 240 within the process chamber 200. At least one of the walls 202, 204, 206, 208 is electrically grounded. The front wall 206 includes a front substrate transfer port 218 and the back wall 208 includes a back substrate transfer port 232 that facilitates substrate entry and exit from the processing chamber 200. The front transfer port 218 and the back transfer port 232 may be slit valves or other suitable sealable doors that can maintain vacuum within the processing chamber 200. The transfer ports 218, 232 may be coupled to a transfer chamber, load lock chamber and/or other chambers of a substrate processing system.

One or more PVD targets 220 may be mounted to the top wall 204 to provide a material source that can be sputtered from the target 220 and deposited onto the surface of the substrate 250 during a PVD process. The target 220 may be fabricated from a material utilized for deposition species. A high voltage power supply, such as a power source 230, is connected to the target 220 to facilitate sputtering materials from the target 220. In one embodiment, the target 220 may be fabricated from a material containing zinc (Zn) metal. In another embodiment, the target 220 may be fabricated from materials including metallic zinc (Zn), zinc alloy, zinc oxide and the like. Different dopant materials, such as boron containing materials, titanium containing materials, tantalum containing materials, tungsten containing materials, aluminum containing materials, and the like, may be doped into a zinc containing base material to form a target with a desired dopant concentration. In one embodiment, the dopant materials may include one or more of boron containing materials, titanium containing materials, tantalum containing materials, aluminum containing materials, tungsten containing materials, alloys thereof, combinations thereof and the like. In one embodiment, the target 220 may be fabricated from a zinc oxide material having dopants, such as, titanium oxide, tantalum oxide, tungsten oxide, aluminum oxide, aluminum metal, boron oxide and the like, doped therein. In one embodiment, the dopant concentration in the zinc containing material comprising the target 220 is controlled to less than about 10 percent by weight.

In one embodiment, the target 220 is fabricated from a zinc and aluminum alloy having a desired ratio of zinc element to aluminum element. The aluminum elements comprising the target 220 assists in maintaining the target conductivity within a desired range so as to efficiently enable a uniform sputter process across the target surface. The aluminum elements in the target 220 are also believed to increase film transmittance when sputtered off and deposited onto the substrate 250. In one embodiment, the concentration of the aluminum element comprising the zinc target 220 is controlled to less than about 5 percent by weight. In embodiments wherein the target 220 is fabricated from ZnO and Al₂O₃ alloy, the Al₂O₃ dopant concentration in the ZnO base target material is controlled to less than about 2 percent by weight, such as less than 0.5 percent by weight, for example, about 0.25 percent by weight.

Optionally, a magnetron assembly (not shown) may be optionally mounted above the target 220 which enhances efficient sputtering materials from the target 220 during processing. Examples of the magnetron assembly include a linear magnetron, a serpentine magnetron, a spiral magnetron, a double-digitated magnetron, a rectangularized spiral magnetron, among others.

A gas source 228 supplies process gases into the processing volume 240 through a gas supply inlet 226 formed through the top wall 204 and/or other wall of the chamber 200. In one embodiment, process gases may include inert gases, non-reactive gases, and reactive gases. Examples of process gases that may be provided by the gas source 228 include, but not limited to, argon gas (Ar), helium (He), nitrogen gas (N₂), oxygen gas (O₂), H₂, NO₂, N₂O and H₂O among others. It is noted that the location, number and distribution of the gas source 228 and the gas supply inlet 226 may be varied and selected according to different designs and configurations of the specific processing chamber 200.

A pumping device 242 is coupled to the process volume 240 to evacuate and control the pressure therein. In one embodiment, the pressure level of the interior processing region 240 of the process chamber 200 may be maintained at about 1 Torr or less. In another embodiment, the pressure level within the process chamber 100 may be maintained at about 10⁻³ Torr or less. In yet another embodiment, the pressure level within the process chamber 200 may be maintained at about 10⁻⁵ Torr to about 10⁻⁷ Torr. In another embodiment, the pressure level of the process chamber 100 may be maintained at about 10⁻⁷ Torr or less.

A substrate carrier system 252 is disposed in the interior processing region 240 to carry and convey a plurality of substrates 250 disposed in the processing chamber 200. In one embodiment, the substrate carrier system 252 is disposed on the bottom wall 202 of the chamber 200. The substrate carrier system 252 includes a plurality of cover panels 214 disposed among a plurality of rollers 212. The rollers 212 may be positioned in a spaced-apart relationship. The rollers 212 may be actuated by actuating device (not shown) to rotate the rollers 212 about an axis 264 fixedly disposed in the processing chamber 200. The rollers 212 may be rotated clockwise or counter-clockwise to advance (a forward direction shown by arrow 216a) or backward (a backward direction shown by arrow 216b) the substrates 250 disposed thereon. As the rollers 212 rotate, the substrate 250 is advanced over the cover panels 214. In one embodiment, the rollers 212 may be fabricated from a metallic material, such as Al, Cu, stainless steel, or metallic alloys, among others.

A top portion of the rollers 212 is exposed to the processing region 240 between the cover panels 214, thus defining a substrate support plane that supports the substrate 250 above the cover panels 214. During processing, the substrates 250 enter the processing chamber 200 through the back access port 232. One or more of the rollers 212 are actuated to rotate, thereby advancing the substrate 250 across the rollers 212 in the forward direction 216a through the processing region 240 for deposition. As the substrate 250 advances, the material sputtered from the target 220 falls down and deposits on the substrate 250 to form a TCO layer with desired film properties. As the substrate 250 continues to advance, the materials sputtered from different targets 220 are consecutively deposited on the substrate surface, thereby forming a desired layer of TCO film on the substrate surface.

In order to deposit the TCO layer on the substrate 250 with high quality, an insulating member 210 electrically isolates the rollers 212 from ground. The insulating member 210 supports the rollers 212 while interrupting the electrical path between the rollers 212 and a grounded surface, such as the processing chamber 200. As the rollers 212 are insulated from ground, the substrate 250 supported thereon is maintained in an electrically floating position, thereby assisting accumulating ions, charges, and species from the plasma on the substrate surface. The accumulation of the ions and plasma on the substrate surface helps retain reactive species on the substrate surface and allows the active species to have sufficient time to pack atoms on the substrate surface, thereby improving the quality of the deposited TCO layer, such as providing high film density. Accordingly, unwanted defects, such as voids or irregular atoms/grain arrangement may be reduced and/or eliminated, thereby providing a TCO layer having desirable high film density and low film resistivity.

In one embodiment, the insulating mechanism 210 may be in form of an insulating pad fabricated from an insulating material, such as rubber, glass, polymer, plastic, and polyphenylene sulfide (PPS), polyetheretherketone (PEEK) or any other suitable insulating materials that can provide insulation to the rollers to the bottom wall 202 of the processing chamber 200. In one embodiment, the insulating pad 210 is a non-conductive material, such as polyphenylene sulfide (PPS), polyetheretherketone (PEEK), or the like.

A controller 248 is coupled to the process chamber 200. The controller 248 includes a central processing unit (CPU) 260, a memory 258, and support circuits 262. The controller 248 is utilized to control the process sequence, regulating the gas flows from the gas source 228 into the chamber 200 and controlling ion bombardment of the target 220. The CPU 260 may be of any form of a general purpose computer processor that can be used in an industrial setting. The software routines can be stored in the memory 258, such as random access memory, read only memory, floppy or hard disk drive, or other form of digital storage. The support circuits 262 are conventionally coupled to the CPU 260 and may comprise cache, clock circuits, input/output subsystems, power supplies, and the like. The software routines, when executed by the CPU 260, transform the CPU into a specific purpose computer (controller) 248 that controls the process chamber 200 such that the processes are performed in accordance with the present invention. The software routines may also be stored and/or executed by a second controller (not shown) that is located remotely from the chamber 200.

During processing, as the substrate 250 is advanced by the roller 212, the material is sputtered from the target 220 and deposited on the surface of the substrate 250. The target 220 is biased by the power source 230 to maintain a plasma 222 formed from the process gases supplied by the gas source 228 and biased toward the substrate surface (as shown by arrows 224). The ions from the plasma are accelerated toward and strike the target 220, causing target material to be dislodged from the target 220. The dislodged target material and process gases form a layer on the substrate 214 with a desired composition.

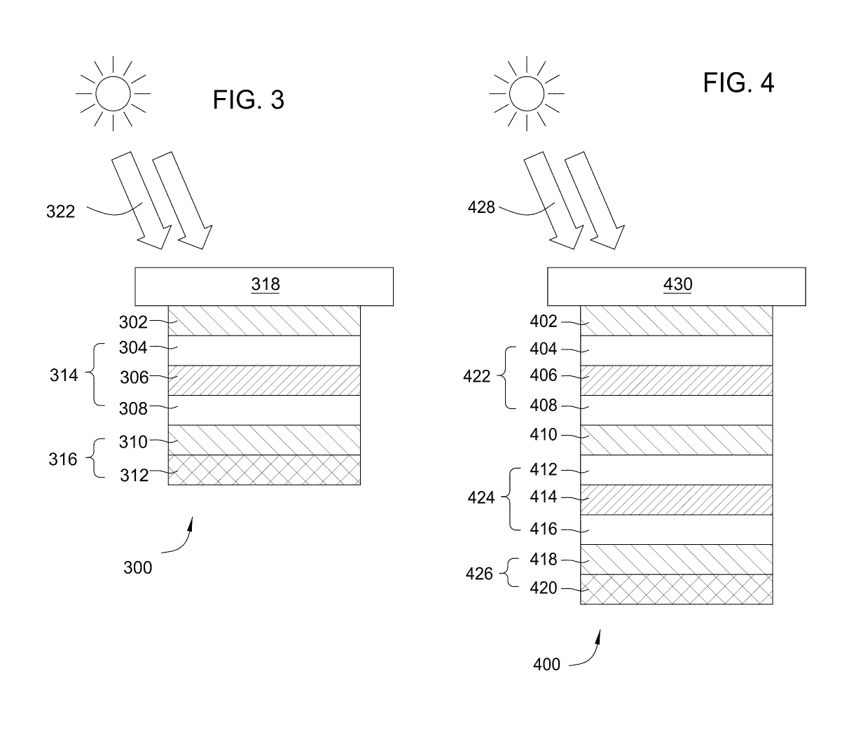

FIG. 3 depicts an exemplary cross sectional view of an amorphous silicon-based thin film PV solar cell 300 in accordance with one embodiment of the present invention. The amorphous silicon-based thin film PV solar cell 300 includes a substrate 318. The substrate 318 may be thin sheet of metal, plastic, organic material, silicon, glass, quartz, or polymer, or other suitable material. In one embodiment, the substrate 318 is a transparent substrate. The substrate 318 may have a surface area greater than about 1 square meter, such as greater than about 2 square meters. Alternatively, the thin film PV solar cell 300 may also be fabricated as polycrystalline, microcrystalline or other type of silicon-based thin films as needed.

A photoelectric conversion unit 314 is formed on a transparent conductive layer, such as a TCO layer 302, disposed on the substrate 318. The photoelectric conversion unit 314 includes a p-type semiconductor layer 304, a n-type semiconductor layer 308, and an intrinsic type (i-type) semiconductor layer 306 sandwiched therebetween as a photoelectric conversion layer. An optional dielectric layer (not shown) may be disposed between the substrate 314 and the TCO layer 302, between the TCO layer 302 and the p-type semiconductor layer 304, or between the intrinsic type (i-type) semiconductor layer 306 and the n-type semiconductor layer 308 as needed. In one embodiment, the optional dielectric layer may be a silicon layer including amorphous or polysilicon, SiON, SiN, SiC, SiOC, silicon oxide (SiO₂) layer, doped silicon layer, or any suitable silicon containing layer. In another embodiment, the optional dielectric layer may be a titanium based layer such as titanium oxide to act as a barrier to impurities that may be present in the substrate 318.

The p-type and n-type semiconductor layers 304, 308 may be silicon based materials doped by an element selected either from group III or V. A group III element doped silicon film is referred to as a p-type silicon film, while a group V element doped silicon film is referred to as a n-type silicon film. In one embodiment, the n-type semiconductor layer 308 may be a phosphorus doped silicon film and the p-type semiconductor layer 304 may be a boron doped silicon film. The doped silicon films 304, 308 include an amorphous silicon film (a-Si), a polycrystalline film (poly-Si), and a microcrystalline film (μc-Si) with a total thickness between around 5 nm and about 50 nm. Alternatively, the doped element in semiconductor layers 304, 308 may be selected to meet device requirements of the PV solar cell 300. The n-type and p-type semiconductor layers 304, 308 may be deposited by a CVD process or other suitable deposition process.

The i-type semiconductor layer 306 is a non-doped type silicon based film. The i-type semiconductor layer 306 may be deposited under process condition controlled to provide film properties having improved photoelectric conversion efficiency. In one embodiment, the i-type semiconductor layer 306 may be fabricated from i-type polycrystalline silicon (poly-Si), i-type microcrystalline silicon film (μc-Si), amorphous silicon (a-Si), or hydrogenated amorphous silicon (a-Si:H).

After the photoelectric conversion unit 314 is formed on the TCO layer 302, a back reflector 316 is formed on the photoelectric conversion unit 314. In one embodiment, the back reflector 316 may be formed by a stacked film that includes a TCO layer 310, and a conductive layer 312. The conductive layer 312 may be at least one of Ti, Cr, Al, Ag, Au, Cu, Pt, or their alloys. The TCO layer 310 may be fabricated from a material similar to the TCO layer 302 formed on the substrate 318. The TCO layers 302, 310 may be fabricated from a selected group consisting of tin oxide (SnO₂), indium tin oxide (ITO), zinc oxide (ZnO), or combinations thereof. In one exemplary embodiment, the TCO layers 302, 310 may be fabricated from a ZnO layer having a desired Al₂O₃ dopant concentration formed in the ZnO layer.

In embodiments depicted in FIG. 3, at least one of the TCO layers 302, 310 is fabricated an etched utilizing the nitric acid and acetic acid chemistry of the present invention. The sputter deposition process of TCO layers 302, 310 may be performed in the processing chamber 100, as described in FIG. 1 or the process chamber 200, as described in FIG. 2.

FIG. 4 depicts an exemplary cross sectional view of a tandem type PV solar cell 400 fabricated in accordance with another embodiment of the present invention. Tandem type PV solar cell 400 has a similar structure of the PV solar cell 300 including a bottom TCO layer 402 formed on the substrate 430 and a first photoelectric conversion unit 422 formed on the TCO layer 402. The first photoelectric conversion unit 422 may be μc-Si based, poly-silicon or amorphous based photoelectric conversion unit as described with reference to the photoelectric conversion unit 314 of FIG. 3. An intermediate layer 410 may be formed between the first photoelectric conversion unit 422 and a second photoelectric conversion unit 424. The intermediate layer 410 may be a TCO layer sputter deposited. Alternatively, the intermediate layer 410 may be a SiO, SiC, SiON, or other suitable doped silicon alloy layer. The combination of the first underlying conversion unit 422 and the second photoelectric conversion unit 424 as depicted in FIG. 4 increases the overall photoelectric conversion efficiency.

The second photoelectric conversion unit 424 may be μc-Si based, polysilicon or amorphous based, and have an μc-Si film as the i-type semiconductor layer 414 sandwiched between a p-type semiconductor layer 412 and a n-type semiconductor layer 416. A back reflector 426 is disposed on the second photoelectric conversion unit 424. The back reflector 426 may be similar to back reflector 316 as described with reference to FIG. 3. The back reflector 426 may comprise a conductive layer 420 formed on a top TCO layer 418. The materials of the conductive layer 420 and the TCO layer 418 may be similar to the conductive layer 312 and TCO layer 310 as described with reference to FIG. 3.

It has surprisingly been found that acceptable film properties and texturing results can be achieved by a ‘cold’ PVD process followed by an annealing process and an etching process or by performing the ‘cold’ PVD process followed by etching and then annealing. The PVD process may be accomplished without providing any additional heating beyond the heating that results from the plasma generated in the chamber. Thus, the process is considered to be a ‘cold’ process because the substrate is not actively heated. In one embodiment, the process may be performed at room temperature. In another embodiment, the process temperature may be between about 23 degrees Celsius to about 30 degrees Celsius.

In order to deposit the TCO, a substrate may be placed into a sputter process chamber for depositing the TCO layer onto the substrate. A process gas mixture is supplied into the sputter process chamber. The process gas mixture supplied into the sputter process chamber bombards the source material from the target and reacts with the sputtered material to form the desired TCO layer on the substrate surface. In one embodiment, the gas mixture may include reactive gas, non-reactive gas, and the like. Examples of non-reactive gas include, but not limited to, inert gas, such as Ar, He, Xe, and Kr, or other suitable gases. Examples of reactive gas include, but not limited to, O₂, N₂, N₂O, NO₂, H₂, NH₃, H₂O, among others. Non-reactive gases may be supplied when the sputtering process is an RF, DC or AC sputtering process in which the sputtering target comprises the TCO material to be deposited such as ZnO. When the sputtering process is a reactive sputtering process, the sputtering target may comprise the metal for the TCO, such as zinc, which reacts with the reactive gas to deposit ZnO on the substrate.

In one embodiment, the argon (Ar) gas supplied into the sputter process chamber assists in bombarding the target to sputter materials from the target surface. The sputtered materials from the target react with the reactive gas in the sputter process chamber, thereby forming a TCO layer having desired film properties on the substrate. The TCO layer formed at different location of the photoelectric conversion unit may have different film properties to achieve different current conversion efficiency requirements. For example, a bottom TCO layer may require film properties, such as relatively high textured surface, high transparency, and high conductivity. An upper TCO layer may require high transparency as well, however, any surface texturing is much less than that of the bottom TCO layer. The gas mixture and/or other process parameters may be varied during the sputtering deposition process, thereby creating the TCO layer with desired film properties for different film quality requirements. The texturing process will be described below.

After the processing gas is introduced to the chamber, RF power is supplied to the target to sputter the source material from the target which reacts with the gas mixture. It is to be understood that while reference is made to an RF reactive sputtering process, the process of depositing the TCO may be accomplished utilizing a DC or AC reactive or non-reactive sputtering process. Additionally, it is to be understood that the RF reactive sputtering process may be accomplished by introducing reactive gases in addition to inert gases into the processing chamber.

In the embodiment wherein the target is made of Zinc (Zn) and aluminum (Al) metals, the gas mixture supplied for sputtering may include argon and oxygen gas. The argon gas is used to bombard and sputter the target, and the oxygen ions dissociated from the O₂ gas mixture reacts with the zinc and aluminum ions sputtered from the target, forming a zinc oxide (ZnO) and aluminum oxide (Al₂O₃) containing TCO layer on the substrate. The RF, DC or AC power is applied to the target during processing. In the embodiment wherein the target is fabricated from ZnO having Al₂O₃ doped therein, the gas mixture used to bombard the target may include argon but may or may not include O₂ gas. In this embodiment, the oxygen gas may be optionally eliminated as the target provides the oxygen elements that are deposited in the TCO layer. In some embodiments, the hydrogen gas may be used in the gas mixture to assist in bombarding and reacting with the source material from the target regardless of the materials of the target.

While the TCO has been described as being ZnO, it is to be understood that other materials may be used as the TCO such as SnO. Additionally, a dopant need not be present. However, if a dopant is present, the dopant need not be aluminum, but rather, may be any of a number of other dopants such as titanium, tantalum, gallium, cadmium, boron and tin.

Once the TCO has been deposited, the post deposition treatment of the TCO occurs in order to improve film properties and obtain the desired texture of the TCO. The post deposition treatment involves annealing the substrate and etching the TCO. Depending upon the desired final product, the annealing and the etching may be reversed such that the etching occurs before the annealing. Additionally, after the texture of the TCO has been measured, additional annealing and/or etching may occur if necessary. The annealing and the sputtering may occur in the same chamber. Performing the annealing and sputtering in the same chamber may be beneficial if the annealing is performed after the sputtering and before the texturing. If the texturing is performed before the annealing, it may be beneficial to have a separate annealing chamber.

For the annealing, the substrate (and hence the TCO deposited thereover) is heated to an annealing temperature for a predetermined period of time. In one embodiment, the annealing temperature may be between about 250 degrees Celsius to about 600 degrees Celsius. In one embodiment, the annealing may occur for about 15 minutes to about 60 minutes. The annealing densifies the deposited TCO and causes the grains to arrange into a more uniform structure. The annealing may occur in numerous environments. In one preferred embodiment, the annealing occurs in an environment of N₂ and H₂ forming gas. In another preferred embodiment, the annealing occurs in an environment of Ar and H₂. In another preferred embodiment, the annealing occurs in an environment of Ar. It is contemplated that other gases may be used as well such as ammonia, N₂O, NO, NO₂, hydrazine, O₂, CO, CO₂, water vapor or combinations thereof. The annealing may increase the transmittance of the TCO to greater than 80 percent and decrease the Rs to about 10 ohm/sq or lower.

The etching textures the TCO. In one embodiment, the etching may comprise a wet etching process. The etching may occur for a time period of between about 20 seconds to about 120 seconds. The etching chemistry may be chosen based upon the desired texturing to be obtained. For example, the different etching chemistries will affect the shape of the texture. A pyramid or pointy roughness may not be beneficial because of how the light reflects and refracts through the TCO. A rounded shaped on the surface may be better than a pointy shape. The material of the TCO will also affect the etching rate and how the etching occurs. Thus, the etching chemistry for a ZnO TCO may be different than the etching chemistry for a SnO TCO.

The goal for the final product of the TCO layer is to have a high haze and a low resistivity. When the TCO is etched, the TCO is textured and thus, the top surface of the TCO may not be perfectly planar which may increase the resistivity. However, the etching increases the haze by texturing the surface to achieve better light trapping and improve solar cell efficiency. A happy balance should be struck between the resistivity and the haze.

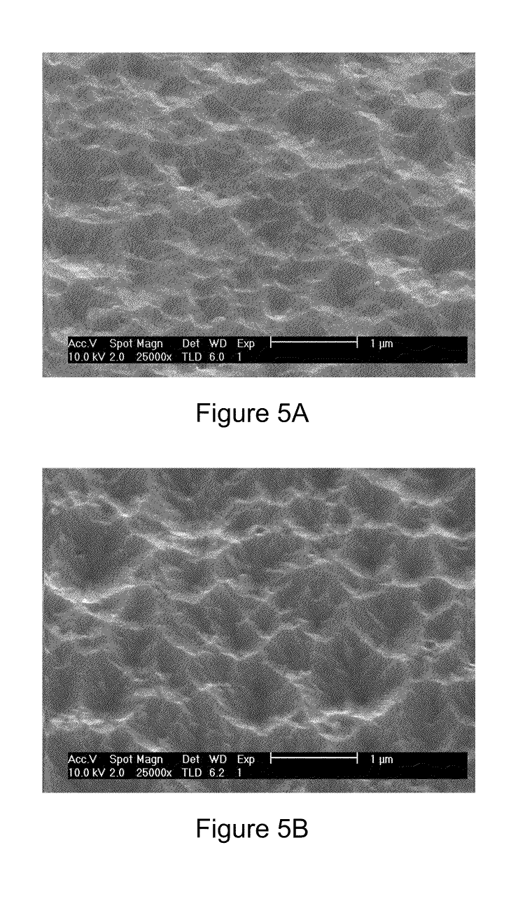

A wet etching process may be used to etch the TCO. Acids such as HCl, HNO₃, H₂SO₄ and H₂PO₄ have been proposed to etch the TCO. These acids have been used in a diluted form such as about 0.2 percent to about 0.5 percent by volume with the remainder water. The primary mechanism of the TCO texturing is believed to be etching around the grain boundaries resulting in surface texturing as shown in FIG. 5A. FIG. 5A shows a TCO surface after etching with a solution of 0.4 volume percent HCl for 30 seconds. The etching depth was measured to be 148 nm, the sheet resistance was 5.8 Ohm/square, the haze was 21 percent and the craters etched into the TCO were shallow.

The acid for etching is selected to obtain a desired pH for the etching solution. In one embodiment, the desired pH level is below about 2. An oxidizer, such as water or hydrogen peroxide may be added. The oxidizer may boost the efficiency of the etching acid. The oxidizer, when joined with the acid, dilutes the acid close to the desired volume percent. The organic or low dielectric constant component, when added to the acid and water, will dilute the acid to the desired volume percentage.

It has surprisingly been found that when nitric acid is used as the acid, an organic modifier, such as acetic acid, can increase the ratio of the haze to etch depth. Nitric acid is not only an acid, but it is also an oxidizer. Hence, an additional oxidizer need not be added to provide the oxidation boost. The acid, including nitric acid, is diluted in water. In one embodiment, the nitric acid is present in an amount of 0.2 percent to about 1 percent by volume. The nitric acid is used as the oxidizer to modify the etch texturing by enhancing the zinc oxidation (in the case of a ZnO TCO) in substoichiometric ZnO films.

Nitric acid, however, dissociates as follows:

HNO₃ [symbol] H⁺+NO₃⁻

When the nitric acid is diluted in water, (which is common to dilute the acid rather than utilizing it in its strongest form), the water tends to cause the nitric acid to dissociate due to the polarity of the water. Therefore, the etching may not be as efficient. By adding an organic component or a low dielectric constant component, the oxidization may be increased. In one embodiment, the component may have a dielectric constant of about 20 or below. In another embodiment, the component may have a dielectric constant of about 10 or below. In still another embodiment, the component may have a dielectric constant of about 6 or below. In another embodiment, the component may have a dielectric constant of about 2 to about 6. Water has a dielectric constant of 80 while acetic acid has a dielectric constant of 6. Thus, acetic acid has a much lower dielectric constant than water and is less polar. Due to the presence of acetic acid, the nitric acid may dissociate less and therefore achieve the desired etching characteristics. In one embodiment, the organic or low dielectric constant component may be present in an amount o between about 10 percent to about 50 percent by volume.

Acetic acid, in particular, has a very low surface tension (˜27 dyne/cm²) compared to water (˜70 dyne/cm²) which contributes to the formation of deeper etch craters as shown in FIG. 5B. It is to be understood that while acetic acid has been described, other components such as ethylene glycol may be used. The etching that occurred to the TCO in FIG. 5B occurred under the conditions of 0.4 volume percent NHO₃, 20 volume percent HC₃OOH for 90 seconds to an etch depth of 150 nm with a sheet resistance of 5.8 Ohm/square and a haze of 33 percent. As compared to FIG. 5A, the craters are deeper and the haze is higher.

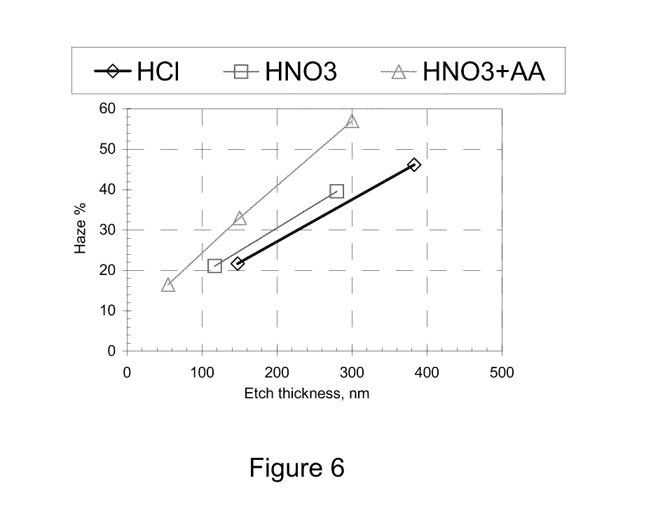

The intent of the organically modified etch chemistry is to change the etch texture morphology to achieve a higher haze at a lower etch depth. In other words, the ratio of the haze to etch depth for an etching chemistry comprising HCl is less than the ratio of haze to etch depth for an etching chemistry comprising nitric and acetic acid. The organically modified etch solution is used to texture ZnO TCO films to achieve superior electrical characteristics of the TCO with about a 30 percent to about 50 percent higher haze to etch depth ratio as compared to an inorganic etch chemistry (i.e., HCl based). The lower surface tension of the acetic acid enhances the etch texture morphology by creating deeper etch craters resulting in a higher haze to etch depth ratio. FIG. 6 is a graph showing the relationship between haze and etching for various etching chemistries.

By utilizing an organic additive or a low dielectric constant additive such as acetic acid along with nitric acid, ZnO TCO layers can be effectively etched to produce a high haze to etch depth ratio and improve the efficiency of solar cell structures.

While the foregoing is directed to embodiments of the present invention, other and further embodiments of the invention may be devised without departing from the basic scope thereof, and the scope thereof is determined by the claims that follow.

1-14. (canceled)

15. A method of forming a transparent conductive oxide layer over a substrate, comprising:
sputter depositing a zinc oxide layer over a substrate; and
etching the zinc oxide layer to form a roughened surface on the zinc oxide layer, the etching comprising exposing the zinc oxide layer to a wet etchant comprising an inorganic nitric acid and an organic acid.

16. The method of claim 15, wherein the inorganic acid is present in an amount of between about 0.2 volume percent to about 1 volume percent.

17. The method of claim 16, wherein the organic acid is present in an amount of between about 10 volume percent to about 50 volume percent.

18. A method of forming a transparent conductive oxide layer over a substrate, comprising:
sputter depositing a zinc oxide layer over a substrate;
etching the sputter deposited zinc oxide layer to form a roughened surface on the zinc oxide layer, the etching comprising exposing the zinc oxide layer to a wet etchant comprising nitric acid and acetic acid; and
annealing the etched zinc oxide layer.

19. The method of claim 18, wherein the nitric acid is present in an amount of between about 0.2 volume percent to about 1 volume percent.

20. The method of claim 19, wherein the acetic acid is present in an amount of between about 10 volume percent to about 50 volume percent.

21. The method of claim 15, wherein the inorganic acid comprises nitric acid.

22. The method of claim 21, wherein the nitric acid is present in an amount of between about 0.2 volume percent to about 1 volume percent.

23. The method of claim 22, wherein the organic acid comprises acetic acid.

24. The method of claim 23, wherein the acetic acid is present in an amount of between about 10 volume percent to about 50 volume percent.

25. The method of claim 23, further comprising annealing the sputter deposited zinc oxide layer prior to etching the zinc oxide layer.

26. The method of claim 15, wherein the organic acid comprises acetic acid.

27. The method of claim 26, wherein the acetic acid is present in an amount of between about 10 volume percent to about 50 volume percent.

28. The method of claim 27, further comprising annealing the sputter deposited zinc oxide layer prior to etching the zinc oxide layer.

29. The method of claim 15, wherein the organic acid comprises ethylene glycol.

30. The method of claim 15, wherein the etching is performed with a solution having a pH of less than about 2 and the organic acid has a dielectric constant of less than about 20.

31. The method of claim 30, wherein the dielectric constant is less than about 10.

32. The method of claim 31, wherein the dielectric constant is less than about 6.

33. The method of claim 15, wherein the organic acid has a surface tension of less than about 30 dyne/cm².

34. The method of claim 15, further comprising annealing the sputter deposited zinc oxide layer prior to etching the zinc oxide layer.
